(19) United States
(12) Patent Application Publication
(10) Pub. No.: US 2003/0112684 A1
(43) Pub. Date: Jun. 19, 2003

(54) DRAM reference cell direct write

(75) Inventor: John Barth JR., Williston, VT (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 10/023,193

(22) Filed: Dec. 17, 2001

(51) Int. Cl. G11C 7/02

(52) U.S. Cl. 365/210

(57) ABSTRACT

The improved reference cell configurations having reduced pre-charge time are obtained by configurations where the reference cell pre-charge level is generated with a voltage regulator (or other power supply) and is directly written into each reference cell. The direct write reference cell configuration improves cycle time of operation when incorporated into sense amplifier and/or DRAM devices.

### BACKGROUND OF THE INVENTION

The present invention relates to improved reference cell configurations, as well as DRAM sensing configurations, especially configurations for use in embedded DRAM (eDRAM) applications.

For DRAM sensing schemes that use reference cells, the voltage in the reference cell must set to a level to balance sense amplifier signal for reading a ‘1’ and the sense amplifier signal for reading ‘0’ from a single device DRAM cell. Previous reference cell pre-charge schemes involved charging two cells to complement levels (one to V_{DD} and one to GND), then shunting via a backdoor equalized device which generates a well-matched V_{DD}/2 level in each reference cell. If the one device DRAM cell takes one time constant to charge, such a reference cell configuration will take two time constants: one to write the first reference cell and one to pre-charge the second reference cell.

Previously, this reference cell scheme was not a severe limiter because the bitline pre-charge, which occurs at the same time as reference cell-pre-charge, had about the same time constant. However, in a mixed technology, like logic based eDRAM, there is typically a significant performance difference between the array devices and standard logic devices. In such instances where bitline pre-charge is implemented with fast logic devices, implementation of a conventional reference cell pre-charge scheme with slow DRAM devices becomes a cycle time limiter.

Thus, there is a need for an improved reference cell scheme to improve the cycle time of DRAM device operation. This need is especially apparent in the context of embedded DRAM devices.

### SUMMARY OF THE INVENTION

The invention provides improved reference cell configurations where the reference cell pre-charge level is generated with a voltage regulator (or other power supply) and is directly written into each reference cell. The invention also encompasses sense amplifier and DRAM devices using the reference cell configurations of the invention, as well as methods of operating such devices.

In one aspect, the invention encompasses a reference cell circuit for supplying a reference voltage, the circuit comprising a first reference cell comprising:

(a) a first storage device for storing the reference voltage,

(b) a first power supply for supplying the reference voltage to the storage device, and

(c) a first output node for outputting the reference voltage from the storage device,

wherein the storage device is electrically isolated from other reference cell storage devices.

In another aspect, the invention encompasses a DRAM device comprising:

(a) an array of DRAM memory cells,

(b) wordlines and bitlines connected to at least some of the memory cells, and

(c) a reference cell circuit for supplying a reference voltage, the reference cell circuit comprising a first reference cell comprising:

(i) a first storage device for storing the reference voltage,

(ii) a first power supply for supplying the reference voltage to the storage device, and

(iii) a first output node for outputting the reference voltage from the storage device,

wherein the storage device is electrically isolated from other reference cell storage devices.

In another aspect, the invention encompasses methods for operating DRAM devices using the reference cell circuit(s) of the invention.

These and other aspects of the invention are described in further detail below.

### BRIEF DESCRIPTION OF THE DRAWINGS

FIG. 1 is a circuit diagram showing a reference cell scheme according to an embodiment of the invention.

FIG. 2 shows a cross-coupled sense amplifier scheme incorporating a reference cell scheme for a folded bitline architecture according to an embodiment of the invention.

FIG. 3 is a waveform simulation of the operation of the sense amplifier reference cell scheme of FIG. 2.

### DETAILED DESCRIPTION OF THE INVENTION

The invention provides improved reference cell configurations where the reference cell pre-charge level is generated with a voltage regulator (or other power supply) and is directly written into each reference cell. The invention also encompasses sense amplifier and DRAM devices using the reference cell configurations of the invention, as well as methods of operating such devices.

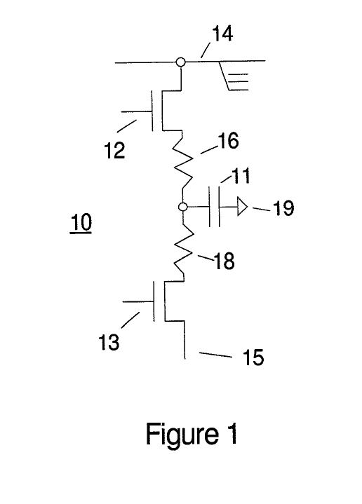

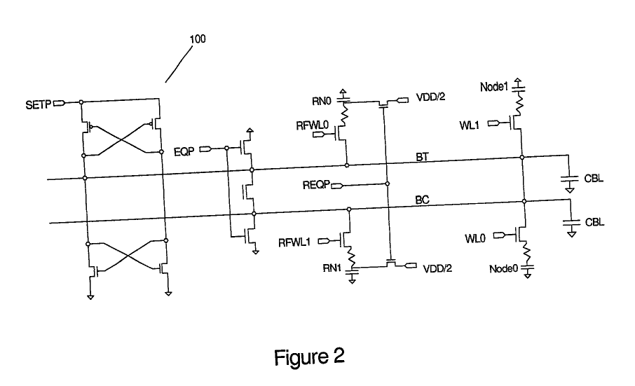

The reference cell of the invention can be embodied as a single reference cell such as shown in FIG. 1 or more preferably as a reference cell pair such as shown in FIG. 2. More preferably, a respective pair of reference cells according to the invention would be associated with each operational sense amplifier used in a DRAM device.

Referring to FIG. 1, a basic reference cell 10 according to an embodiment of the invention comprises a storage device such as capacitor 11 connected to ground 19. Capacitor 11 acts to store the reference cell voltage upon pre-charging. The charging of capacitor 11 is controlled by equalization signal to transistor 12 which controls the connection between capacitor 12 and reference voltage source 14. Reference voltage source 14 may be any desired source, preferably a voltage regulator or other suitable driver. Resistors 16 and 18 in FIG. 1 are parasitic resistance associated with the non-ideal interconnection between the various components. Connection between capacitor 11 and bitline 15 is controlled by the signal to transistor 13. Preferably, transistor 13 is controlled by a signal from a reference wordline which is preferably activated with the activation of an associated real wordline (i.e. a wordline connected to array cells). The reference cell voltage may be set at any desired level according to the implemented sensing design or based on other considerations. Preferably, the reference voltage is about VDD/2.

FIG. 2 shows an embodiment of reference cells according to the invention with a cross-coupled sense amplifier 100. The reference cells have respective capacitors shown at RN0 and RN1. The connection between the capacitors RN0 and RN1 and voltage source labeled VDD/2 is controlled by the reference cell equalization signal REQP. The bitlines are labeled BT and BC respectively, however, it should be noted that either bitline may act as the complement to the other depending on the actual wordline (WL1 or WL0 or other wordline) that is being activated. Representative memory cells from the array are shown as Node0 and Node1, respectively, with effective bitline capacitance CBL. Connection between capacitors RN0, RN1 and their respective bitlines BT, BC is controlled by the signal of respective reference wordlines RFWL0, RFWL1. The signal EQP and associated transistors control far end equalization. The sense amplifier is driven through the signal at SETP. Where the sense amplifier is used in a ground-sense scheme, the need to separately control the NFET side of the sense amplifier can be eliminated.

In another aspect, the invention encompasses a DRAM device comprising:

(a) an array of DRAM memory cells,

(b) wordlines and bitlines connected to at least some of the memory cells, and

(c) a reference cell circuit for supplying a reference voltage, the reference cell circuit comprising a first reference cell comprising:

(i) a first storage device for storing the reference voltage,

(ii) a first power supply for supplying the reference voltage to the storage device, and

(iii) a first output node for outputting the reference voltage from the storage device,

wherein the storage device is electrically isolated from other reference cell storage devices.

The invention also encompasses methods for operating DRAM devices using the reference cell circuit(s) of the invention.

In this scheme, a single reference wordline is activated when any one of a corresponding set of wordlines is activated. When the sense amplifier sets, the activated reference wordline is deactivated, and the corresponding reference cell equalize signal is immediately activated, initiating reference pre-charge immediately. The complementary reference wordline is held in the off state for the entire cycle.

Additional features of the scheme of the invention include disabling only the reference cell equalize of the selected reference wordline. This increases the effective charging time of the selected cell by locally charging unselected reference cells for the entire cycle and using them as a charge reservoir. By eliminating the need to activate the unselected reference wordline (to write the complementary reference cell), fewer wordlines are activated in a given cycle and wordline high supply (VPP) current is reduced. For example, two reference wordlines, two reference cell equalize lines, and one real wordline would create an equivalent VPP current of 5 wordlines per cycle. This scheme only requires activation of one reference wordline, one reference equalize line and one real wordline, reducing the equivalent wordlines activated to three. In a design with bitline twisting that requires four reference wordlines, four reference equalize lines and one real wordline (9 total), the scheme of the invention would still only require three equivalent wordlines, offering an even a greater savings.

Direct reference cell write eliminates retention requirements on reference cell by supplying constant voltage level during retention pauses. In DRAM arrays that use a negative wordline bias scheme to improve retention, direct reference cell write removes the requirement to hold unselected reference wordlines at the negative supply level. Using ground (GND) as a reference wordline down level further reduces VWL power supply requirements and improves lifetime and reliability of the reference cells by reducing voltage across drivers and reference cells.

Preferably, the reference cell voltage is set with a high current regulator , and the reference voltage is distributed on a low impedance network. Such a configuration enables tuning for optimal yield and signal margin testing at-speed.

Direct reference cell write scheme not only improves cycle time but allows the reference level to be regulated, enabling signal/retention time optimization and high speed signal margin testing. As an added benefit, signal margin control is amplified by the cell/bitline transfer ratio and the current requirements are reduced by the same transfer ratio, simplifying the regulator design when compared to VDD/2 bitline pre-charge.

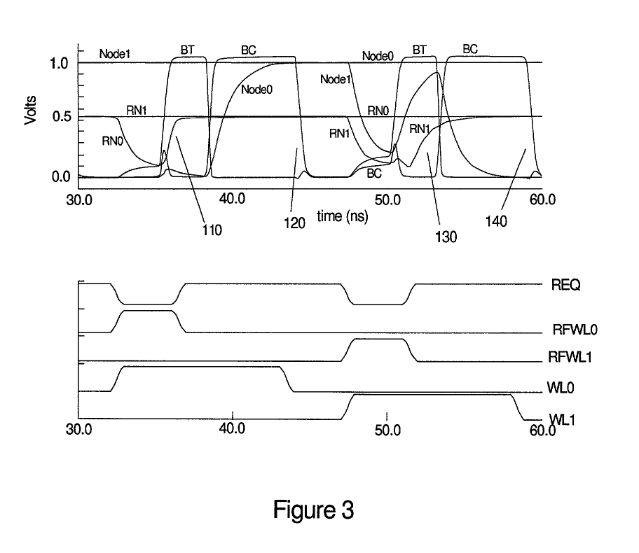

Operation of the configuration of FIG. 2 is simulated by waveforms plotted in FIG. 3. In the first portion of FIG. 3, a “0” is read from Node0 in the following manner. Node0 is connected to BC with activation of WL0, for the case of read “0”, there exists no voltage difference between Node0, previously written low (“0”), and BC, pre-conditioned low (“0”); no charge is transferred, and BC remains low. RN0, accessed for the read of any word-line connected to BC, is connected to BT with activation of RFWL0. With existence of voltage difference between RN0, written to VDD/2 directly, and BT, pre-conditioned low (“0”), charge will flow from RN0 coupling BT up by the following charge transfer equation:

ΔV=(V_{node}−V_{bl})*(C_{cell}/(C_{cell}+C_{bl}))

C_{cell}/(C_{cell}+C_{bl}) is referred to as the transfer ratio and is typically about 0.20. For the waveforms shown, Vnode (Voltage of RN0) is 500 mV and couples the Vbl (Voltage of BT) to 100 mV.

The cross couple amplifier 100, can now reliably amplify the 100 mV difference between BT and BC to 1.0V and initiate RN0 pre-charge show at 110 in FIG. 3 with deactivation of RFWL0 and activation of REQP in FIG. 2. Opposite data is shown to written onto BC and subsequently Node0 charging to “1” at 115 in FIG. 3. Bitline pre-charge is shown at 120 in FIG. 3, where BT and BC are pre-conditioned low with activation of EQP in FIG. 2.

In the second portion of FIG. 3, a “1” is read from Node1 in the following manner. Node1 is connected to BT with activation of WL1. For the case of read “1”, there exists a voltage difference between Node1, previously written low (“1”), and BT, pre-conditioned low (“0”); charge will flow from Node1 to BT, coupling BT up by the charge transfer equation previously shown. For the waveforms shown, Vnode (Voltage of Node1) is 1V and couples Vbl (Voltage of BT) to 200 mV. RN1, accessed for the read of any word-line connected to BT, is connected to BC with activation of RFWL1. Similarly to the read “0” case, with existence of voltage difference between RN1, written to VDD/2 directly, and BC, pre-conditioned low (“0”), charge will flow from RN1 coupling BC up by the previously shown charge transfer equation. Similarly to the read “0” case, for the waveforms shown, RN1 is 500 mV and couples the BC to 100 mV.

The cross couple amplifier 100, can now reliably amplify the 100 mV difference between BT and BC to 1.0V and initiate RN1 pre-charge show at 130 in FIG. 3 with deactivation of RFWL1 and activation of REQP in FIG. 2. Opposite data is shown to written onto BT and subsequent Node1 charging to “0” at 135 in Figure. Bitline pre-charge is shown at 140, where BT and BC are pre-conditioned low with EQP in FIG. 2.

Implementation of reference cells provides both static and dynamic bitline balancing. Static bitline balancing is achieved by placing the equivalent capacitance of a reference cell on the reference bitline. Without a reference cell, the active bitline would see the extra capacitance of the selected cell's storage capacitor, creating a 20% capacitance mismatch between bitline and reference bitline. Transient bitline balancing is accomplished by switching of the reference wordline to provide dynamic coupling to the reference bitline that is equivalent to the coupling from the selected wordline to the active bitline. The reference cell and reference wordline minimize the mismatch and coupling, allowing the sense system to operate on less stored charge which enables increased performance and improved retention characteristics.

The DRAM devices using the reference cell scheme of the invention would typically comprise:

(a) an array of DRAM memory cells,

(b) wordlines and bitlines connected to at least some of the memory cells, and

(c) a reference cell circuit of the invention.

The reference cell circuit would typically be integrated into the sense amplifier layout, such as shown in FIG. 2. DRAM designs using the reference cell configuration of the invention are especially suited for use as embedded DRAM macros.

What is claimed is:

1. A reference cell circuit for supplying a reference voltage, said circuit comprising a first reference cell comprising:
(a) a first storage device for storing said reference voltage,
(b) a first power supply for supplying said reference voltage to said storage device, and
(c) a first output node for outputting said reference voltage from said storage device,
wherein said storage device is electrically isolated from other reference cell storage devices.

2. The reference cell circuit of claim 1 wherein said storage device is a capacitor.

3. The reference cell circuit of claim 1 wherein said power supply comprises a first connection to a voltage regulator circuit.

4. The reference cell circuit of claim 1 further comprising:
(d) a first switch positioned between said power supply and said storage device, said first switch controlling electrical connection between power supply and said storage device.

5. The reference cell circuit of claim 4 further comprising:
(e) a second switch positioned between said storage device and said output node, said second switch controlling electrical connection between said storage device and said output node.

6. The reference cell circuit of claim 5 wherein said first switch is a transistor having a gate connected to an equalization command signal.

7. The reference cell of claim 6 wherein said second switch is a transistor having a gate connected to a reference wordline signal.

8. The reference cell of claim 1 wherein said output node is electrically connected to a first bitline of a DRAM array.

9. The reference cell circuit of claim 8 further comprising a second reference cell comprising:
(a) a second storage device for storing said reference voltage,
(b) a second power supply for supplying said reference voltage to said second storage device, and
(c) a second output node for outputting said reference voltage from said second storage device, said second output node being electrically connected to a second bitline of said DRAM array,
wherein said second storage device is electrically isolated from other reference cell storage devices, and at least one of said first and second bitlines can act as a complement to the other.

10. The reference cell circuit of claim 9 wherein said first and second power supplies respectively comprise first and second connections to a common voltage regulator circuit.

11. A DRAM device comprising:
(a) an array of DRAM memory cells,
(b) wordlines and bitlines connected to at least some of said memory cells, and
(c) a reference cell circuit for supplying a reference voltage, said reference cell circuit comprising a first reference cell comprising:
(i) a first storage device for storing said reference voltage,
(ii) a first power supply for supplying said reference voltage to said storage device, and
(iii) a first output node for outputting said reference voltage from said storage device,
wherein said storage device is electrically isolated from other reference cell storage devices.

12. The DRAM device of claim 11 wherein said storage device is a capacitor.

13. The DRAM device of claim 11 wherein said power supply comprises a first connection to a voltage regulator circuit.

14. The DRAM device of claim 11 further comprising:
(d) a first switch positioned between said power supply and said storage device, said first switch controlling electrical connection between power supply and said storage device.

15. The DRAM device of claim 14 further comprising:
(e) a second switch positioned between said storage device and said output node, said second switch controlling electrical connection between said storage device and said output node.

16. The DRAM device of claim 15 wherein said first switch is a transistor having a gate connected to an equalization command signal and said second switch is a transistor having a gate connected to a reference wordline signal.

17. The DRAM device claim 11 wherein said output node is electrically connected to a first bitline of a DRAM array.

18. The DRAM device of claim 17 further comprising a second reference cell comprising:
(a) a second storage device for storing said reference voltage,
(b) a second power supply for supplying said reference voltage to said second storage device, and
(c) a second output node for outputting said reference voltage from said second storage device, said second output node being electrically connected to a second bitline of said DRAM array,
wherein said second storage device is electrically isolated from other reference cell storage devices, and at least one of said first and second bitlines can act as a complement to the other.

19. The DRAM device of claim 18 wherein said first and second power supplies respectively comprise first and second connections to a common voltage regulator circuit.

20. The DRAM device of claim 11 wherein said device is an embedded DRAM.
